(19) United States
(12) Patent Application Publication
(10) Pub. No.: US 2012/0125426 A1
(43) Pub. Date: May 24, 2012

(54) COMPOUND SEMICONDUCTOR SOLAR CELL

(75) Inventor: Yong-Duck CHUNG, Daejeon (KR)

(73) Assignee: ELECTRONICS AND TELECOMMUNICATIONS RESEARCH INSTITUTE, Daejeon (KR)

(21) Appl. No.: 13/191,877

(22) Filed: Jul. 27, 2011

(30) Foreign Application Priority Data
Nov. 22, 2010 (KR) 10-2010-0116322

(51) Int. Cl. H01L 31/0224

(52) U.S. Cl. 136/256

(57) ABSTRACT

Provided is a compound semiconductor solar cell. The compound semiconductor solar cell may include a back electrode provided on a substrate, a hole injection layer provided on the back electrode, a copper indium gallium selenide (CIGS) based optical absorption layer provided on the hole injection layer, and a front transparent electrode provided on the optical absorption layer.

### CROSS-REFERENCE TO RELATED APPLICATIONS

This U.S. non-provisional patent application claims priority under 35 U.S.C. §119 of Korean Patent Applications No. 10-2010-0116322, filed on Nov. 22, 2010, the entire contents of which are hereby incorporated by reference.

### BACKGROUND

The present disclosure herein relates to a compound semiconductor solar cell, and more particularly, to a copper indium gallium selenide (CIGS) based thin film solar cell.

Due to a limitation of insufficient silicon raw materials caused by the growth of solar cell market, interest in thin film solar cells is increasing. A thin film solar cell, according to its material, may be classified into an amorphous or crystalline silicon thin film solar cell, a copper indium gallium selenide (CIGS) based thin film solar cell, a cadmium telluride (CdTe) thin film solar cell, a dye-sensitized solar cell, etc. An optical absorption layer of a CGIS-based thin film solar cell is composed of I-III-VI₂ group compound semiconductors (e.g., CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂) represented by copper indium diselenide (CuInSe₂). The optical absorption layer has a direct transition type energy bandgap and a high optical absorption coefficient such that a highly efficient solar cell can be manufactured in the form of a thin film having a thickness of about 1-2 μm.

It is known that the efficiency of a CGIS-based thin film solar cell is not only higher than some commercialized thin film solar cells such as amorphous silicon, CdTe and the like, but also close to a typical polycrystalline silicon solar cell. Also, the CGIS-based thin film solar cell not only can be manufactured with lower cost constituent materials than other types of solar cell materials and flexible, but has characteristics in which its performance is not deteriorated for a long period of time.

### SUMMARY

The present disclosure provides a compound semiconductor solar cell having improved efficiency.

Embodiments of the inventive concept provide compound semiconductor solar cells including: a back electrode provided on a substrate; a hole injection layer provided on the back electrode; a copper indium gallium selenide (CIGS) based optical absorption layer provided on the hole injection layer; and a front transparent electrode provided on the optical absorption layer.

In some embodiments, a difference between a valence band of the hole injection layer and a valence band of the p-type semiconductor optical absorption layer is larger than a difference between a conduction band of the hole injection layer and the valence band of the p-type semiconductor optical absorption layer.

In other embodiments, the hole injection layer may include molybdenum oxide (MoOx, 1≦x≦4). The molybdenum oxide (MoOx, 1≦x≦4) may be molybdenum trioxide (MoO₃).

In still other embodiments, the hole injection layer is formed with a thickness of about 0.001 μm to about 1.0 μm.

In even other embodiments, the optical absorption layer includes I-III-VI₂ group compound semiconductors.

In yet other embodiments, the above compound semiconductor solar cells may further include a buffer layer provided between the optical absorption layer and the front transparent electrode.

In further embodiments, the above compound semiconductor solar cells may further include: an anti-reflective layer provided at a portion of region on the front transparent electrode; and a grid electrode which is provided at a side face of the anti-reflective layer and in contact with the front transparent electrode.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view illustrating a copper indium gallium selenide (CIGS) based thin film solar cell according to an embodiment of the inventive concept;

FIG. 2 is a graph showing an energy band diagram of a back electrode of a typical solar cell according to a comparative example;

FIG. 3 is a graph showing an energy band diagram of a back electrode of a solar cell according to an embodiment of the inventive concept; and

FIG. 4 is a flowchart illustrating a manufacturing method of a CIGS-based thin film solar cell according to an embodiment of the inventive concept.

### DETAILED DESCRIPTION OF THE EMBODIMENTS

Preferred embodiments of the present invention will be described below in more detail with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals refer to like elements throughout.

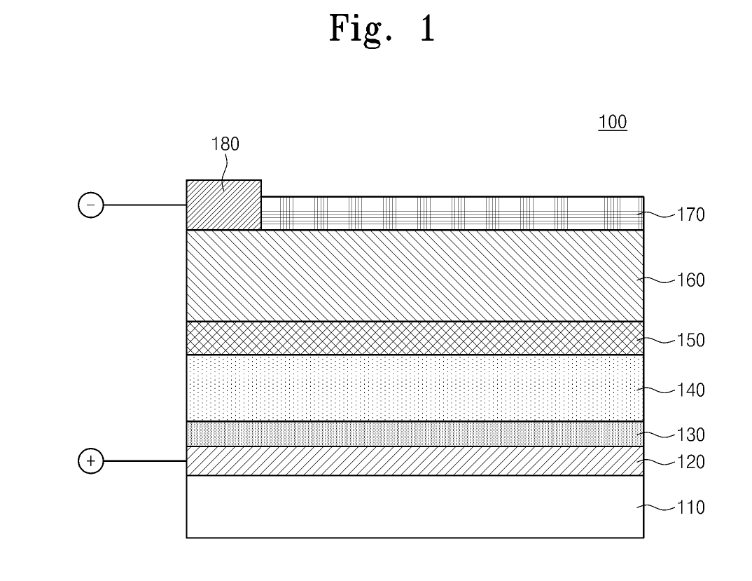

FIG. 1 is a cross-sectional view illustrating a copper indium gallium selenide (CIGS) based thin film solar cell according to an embodiment of the inventive concept.

Referring to FIG. 1, a CIGS-based thin film solar cell 100 according to an embodiment of the inventive concept may include a substrate 110, and a back electrode 120, a hole injection layer 130, a CGIS-based optical absorption layer 140, a buffer layer 150, a front transparent electrode 160, an anti-reflective layer 170 and a grid electrode 180 which are provided sequentially on the substrate 110.

The substrate 110 may be a sodalime glass substrate. The sodalime glass substrate 110 is known to be a relatively low cost substrate material. Also, sodium in the sodalime glass substrate 110 may diffuse into the optical absorption layer 140, thus enabling to improve photovoltaic characteristics of the CIGS-based thin film solar cell 100. Alternatively, the substrate 110 may include a ceramic substrate such as alumina (Al₂O₃), flexible metal substrates such as stainless steel, a cooper (Cu) tape, aluminum (Al), molybdenum (Mo), titanium (Ti), etc., or a flexible poly film such as polyimide.

The back electrode 120 has low resistivity and may have excellent adhesion to a glass substrate such that an exfoliation phenomenon does not occur due to the difference in thermal expansion coefficients.

For example, the back electrode 120 may be composed of molybdenum (Mo). Mo may have high electrical conductivity, characteristics of forming ohmic contacts with other thin films, and high temperature stability under selenium (Se) atmosphere.

The hole injection layer 130 satisfies characteristics in which a difference between a valence band of the hole injection layer 130 and a valence band of the optical absorption layer 140 which is a p-type semiconductor is larger than a difference between a conduction band of the hole injection layer 130 and the valence band of the optical absorption layer 140 which is a p-type semiconductor.

For example, the hole injection layer 130 may be formed to include molybdenum oxide (MoOx, 1≦x≦4). The molybdenum oxide (MoOx, 1≦x≦4) may include molybdenum dioxide (MoO₂) or molybdenum trioxide (MoO₃).

According to an embodiment of the inventive concept, the hole injection layer 130 may be composed of molybdenum trioxide (MoO₃). The molybdenum oxide (MoOx, 1≦x≦4) may change its characteristics depending on oxygen compositions, in which molybdenum trioxide (MoO₃) best represents characteristics as the hole injection layer 130.

The hole injection layer 130 may be provided with a thickness of about 0.001 μm to about 1.0 μm for the performance improvement of the CIGS-based thin film solar cell 100.

The optical absorption layer 140 may be formed of I-III-VI₂ group compound semiconductors. The I-III-VI₂ group compound semiconductors may be chalcopyrite compound semiconductors, for example, CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂, etc. These compound semiconductors may be commonly referred as CIGS-based thin films.

The optical absorption layer 140 may be formed of copper indium gallium diselenide (CuInGaSe₂) having a bandgap energy of about 1.2 eV which is close to the highest efficiency of a typical wafer-type polycrystalline silicon solar cell among single-junction solar cells.

Since differences in lattice parameters and bandgap energies between the optical absorption layer 140 and the front transparent electrode 160 are large, the buffer layer 150 may be provided for a good junction. The buffer layer 150 may have a bandgap energy which is located at an intermediate level between the optical absorption layer 140 and the front transparent electrode 160.

For example, the buffer layer 150 may be formed of a cadmium sulfide (CdS) thin film. The buffer layer 150 may be provided with a thickness of about 500 Å. The CdS thin film has a bandgap energy of about 2.46 eV, and this corresponds to a wavelength of about 550 nm. The CdS thin film is an n-type semiconductor, and a low resistance value may be obtained by doping with indium (In), gallium (Ga) and aluminum (Al), etc.

Since the front transparent electrode 160 is formed at a front face of the CIGS-based thin film solar cell 100 to function as a window, it may be formed of a material that has a high optical transmittance and good electrical conductivity. For example, the front transparent electrode 160 may be formed of a zinc oxide (ZnO) layer. The ZnO layer has a bandgap energy of about 3.3 eV, and may have a high optical transmittance of about 80% or more. The ZnO layer may have a low resistance value of about 1×10⁻⁴ Ωcm by doping with aluminum (Al) or boron (B) and the like. If the boron is doped, a degree of optical transmission in the near-infrared region is increased such that a short-circuit current can be increased.

Alternatively, the front transparent electrode 160 may further include an indium tin oxide (ITO) thin film having excellent electro-optical characteristics on the ZnO thin film. The front transparent electrode 160 may be a stacked layer of an n-type ZnO thin film having a low resistance on an undoped i-type ZnO thin film. The front transparent electrode 160 is an n-type semiconductor such that a pn-junction is formed with the optical absorption layer 140 which is a p-type semiconductor.

The anti-reflective layer 170 may be additionally provided at a portion of region on the front transparent electrode 160. The anti-reflective layer 170 may reduce a reflective loss of solar light incident on the CIGS-based thin film solar cell (100). The efficiency of the CIGS-based thin film solar cell 100 may be improved by the anti-reflective layer 170. For example, the anti-reflective layer 170 may be formed of magnesium fluoride (MgF₂).

The grid electrode 180 may be in contact with the front transparent electrode 160 and provided at one side of the anti-reflective layer 170. The grid electrode 180 is for collecting currents on a surface of the CIGS-based thin film solar cell 100. The grid electrode 180 may be formed of metals such as aluminum (Al) or nickel (Ni)/aluminum (Al), etc. Because solar light does not incident on a portion occupied by the grid electrode 180, it is necessary to minimize the portion.

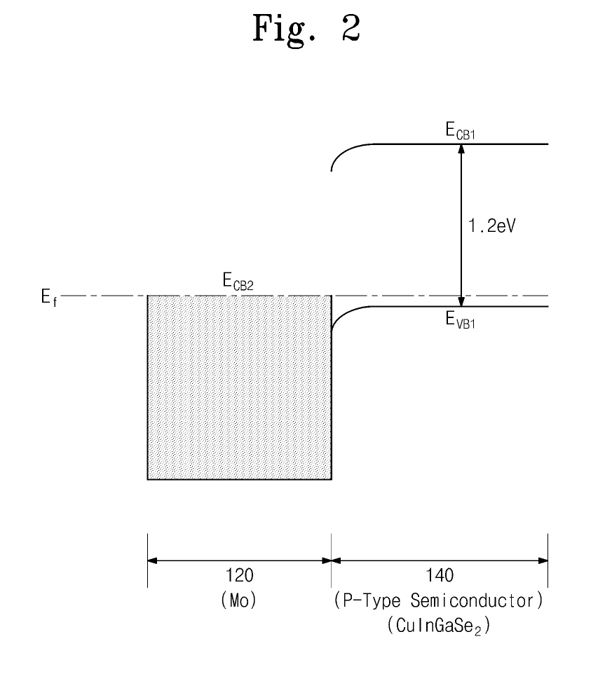

FIG. 2 is a graph showing an energy band diagram of a back electrode of a typical solar cell according to a Comparative Example.

In the comparative example of FIG. 2, a back electrode 120 is a molybdenum (Mo) layer, and an optical absorption layer 140 is a p-type semiconductor CuInGaSe₂ thin film, and no hole injection layer 130 is present between the back electrode 120 and the optical absorption layer 140. The optical absorption layer 140 has a valence band (E_{VB1}) close to the Fermi level (E_{f}), and a bandgap energy of about 1.2 eV, which is an energy difference between a conduction band (E_{CB1}) and the valence band (E_{VB1}). In the back electrode 120, a conduction band (E_{CB2}) coincides with the Fermi level (E_{f}).

At this time, a hole is transferred from the optical absorption layer 140 to the back electrode 120.

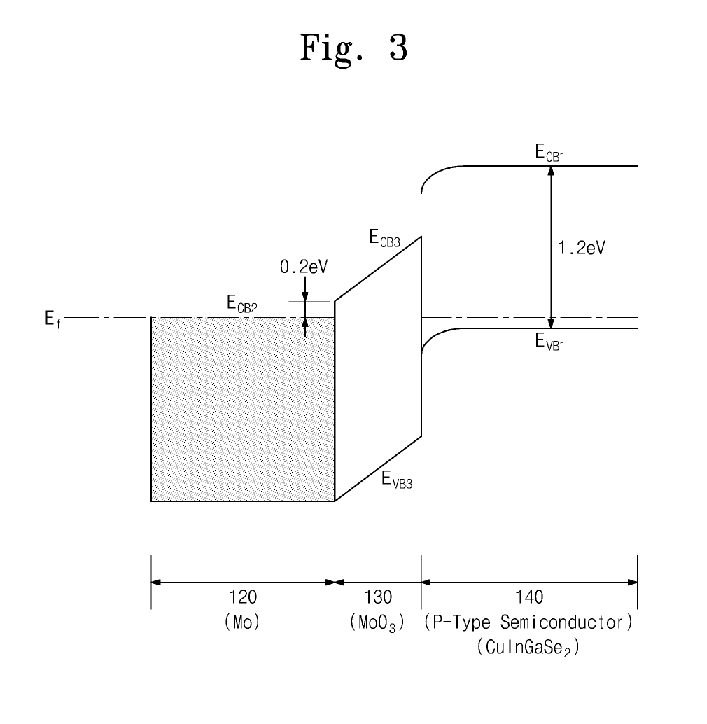

FIG. 3 is a graph showing an energy band diagram of a back electrode of a solar cell according to an embodiment of the inventive concept.

In FIG. 3, according to an embodiment of the inventive concept, the back electrode 120 is a molybdenum (Mo) layer, the hole injection layer 130 is a molybdenum trioxide (MoO₃) layer, and the optical absorption layer 140 is a p-type semiconductor CuInGaSe₂ thin film. The optical absorption layer 140 has a valence band (E_{VB1}) close to the Fermi level (E_{f}), and a bandgap energy of about 1.2 eV, which is an energy difference between a conduction band (E_{CB1}) and the valence band (E_{VB1}). In the back electrode 120, a conduction band (E_{CB2}) coincides with the Fermi level (E_{f}). The hole injection layer 130 has a conduction band (E_{CB3}) close to the Fermi level (E_{f}), an energy difference of about 0.2 eV between the conduction band (E_{CB3}) and the Fermi level (E_{f}), and a bandgap energy of about 3.0 eV.

At this time, the solar cell of FIG. 3 is characterized in that a difference between a valence band (E_{VB3}) of the hole injection layer 130 and the valence band (E_{VB1}) of the p-type semiconductor optical absorption layer 140 is larger than a difference between the conduction band (E_{CB3}) of the hole injection layer 130 and the valence band (E_{VB1}) of the p-type semiconductor optical absorption layer 140. That is, a relation, |(E_{VB1}−E_{VB3})|>|(E_{CB3}−E_{VB1})|, may be established.

Although a hole, which is generated at a pn-junction portion between the optical absorption layer 140 and the front transparent electrode 160 (see FIG. 1), should be generally transferred through the valence band (E_{VB3}) of the MoO₃ layer, the hole will be transferred through the conduction band (E_{CB3}) of the MoO₃ layer instead of the valence band (E_{VB3}) of the MoO₃ layer located deep when satisfying the above relation. That is, the hole will be directly transferred from the valence band (E_{VB1}) of the optical absorption layer 140 to the conduction band (E_{CB3}) of the MoO₃ layer when satisfying the above relation. Therefore, in FIG. 3 rather than FIG. 2, a transfer of the hole from the optical absorption layer 140 to the back electrode 120 is easy. As a result, the transfer of holes generated by solar light is easy so that the efficiency of the CIGS-based thin film solar cell 100 may be enhanced.

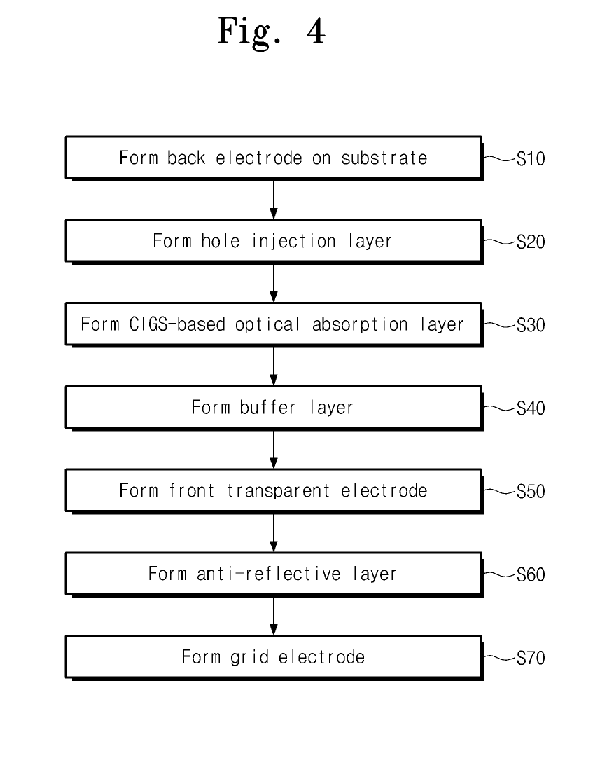

FIG. 4 is a flowchart illustrating a manufacturing method of a CIGS-based thin film solar cell according to an embodiment of the inventive concept.

Referring to FIGS. 1 and 4, in operation S10, a back electrode 120 is formed on a substrate 110. The substrate 110 may be formed of any one of a sodalime glass substrate, a ceramic substrate such as alumina (Al₂O₃), metal substrates such as stainless steel and a cooper tape, etc., or a poly film. According to an embodiment of the inventive concept, the substrate 110 may be formed of sodalime glass.

The back electrode 120 has low resistivity and may be formed of a material which has excellent adhesion to a glass substrate such that an exfoliation phenomenon does not occur due to the difference in thermal expansion coefficients. For example, the back electrode 120 may be formed of molybdenum (Mo). Mo may have high electrical conductivity, characteristics of forming ohmic contacts with other thin films, and high temperature stability under selenium (Se) atmosphere.

The back electrode 120 may be formed by a sputtering method, for example, a typical direct current (DC) sputtering method.

In operation S20, a hole injection layer 130 may be formed on the back electrode 120. The hole injection layer 130 satisfies characteristics in which a difference between the valence band of the hole injection layer 130 and the valence band of the p-type semiconductor optical absorption layer 140 is larger than a difference between the conduction band of the hole injection layer 130 and the valence band of the p-type semiconductor optical absorption layer 140.

For example, the hole injection layer 130 may be formed of molybdenum oxide (MoOx, 1≦x≦4). The molybdenum oxide (MoOx, 1≦x≦4) may include molybdenum dioxide (MoO₂) or molybdenum trioxide (MoO₃). According to an embodiment of the inventive concept, the molybdenum oxide (MoOx, 1≦x≦4) may be molybdenum trioxide (MoO₃). The hole injection layer 130 may be formed with a thickness of about 0.001 μm to about 1.0 μm for the performance improvement of the CIGS-based thin film solar cell 100.

The hole injection layer 130 may be formed by depositing a mixture of a Mo target, an oxygenated compound or a gas containing oxygen as an atomic form and an inert gas by a sputtering method.

The oxygenated compound may include, for example, oxygen, ozone (O₃) or carbon dioxide (CO₂). The gas containing oxygen as an atomic form may be, for example, water vapor (H₂O). The inert gas may be, for example, argon (Ar).

Alternatively, the hole injection layer 130 may be formed by a vacuum deposition of the molybdenum oxide (MoOx, 1≦x≦4). Also, the hole injection layer 130 may be formed by a heat treatment of a Mo thin film under gas atmosphere containing the oxygenated compound or the oxygen as an atomic form.

In operation S30, a CGIS-based optical absorption layer 140 is formed on the hole injection layer 130. The optical absorption layer 140 may be formed of I-III-VI₂ group compound semiconductors. The I-III-VI₂ group compound semiconductors may include chalcopyrite compound semiconductors, for example, CuInSe₂, Cu(In,Ga)Se₂, Cu(Al,In)Se₂, Cu(Al,Ga)Se₂, Cu(In,Ga)(S,Se)₂, (Au,Ag, Cu)(In,Ga,Al)(S,Se)₂, etc. These compound semiconductors may be commonly referred as CIGS-based thin films.

The optical absorption layer 140 may be formed of copper indium gallium diselenide (CuInGaSe₂) having a bandgap energy of about 1.2 eV which is close to the highest efficiency of a typical wafer-type polycrystalline silicon solar cell among single-junction solar cells.

The optical absorption layer 140 may be formed by a physical method or a chemical method. For example, the physical method may include an evaporation method or a mixed method of sputtering and a selenization process. For example, the chemical method may include an electroplating method.

The physical or chemical method may be selected from various manufacturing methods according to types of starting materials (e.g., metal, binary compound, etc.).

The optical absorption layer 140 may be formed by a co-evaporation method with metal elements of copper (Cu), indium (In), gallium (Ga) and selenium (Se) as starting materials.

Alternatively, the optical absorption layer 140 may be formed by synthesizing nano-sized particles (e.g., powders, colloids, etc.), mixing the nano-sized particles with a solvent to generate a mixture, printing the mixture on the hole injection layer 130 in a screen printing method, and reactively sintering the printed mixture.

In operation S40, a buffer layer 150 may be additionally formed on the optical absorption layer 140. Since differences in lattice parameters and bandgap energies between the optical absorption layer 140 and the front transparent electrode 160 are large, the buffer layer 150 may be additionally provided for a good junction. The buffer layer 150 may have a bandgap energy which is located at an intermediate level between the optical absorption layer 140 and the front transparent electrode 160.

For example, the buffer layer 150 may be formed of a cadmium sulfide (CdS) thin film. The CdS thin film may be formed by a chemical bath deposition (CBD) method. The CdS thin film may be formed with a thickness of about 500 Å.

The CdS thin film has a bandgap energy of about 2.46 eV, and this corresponds to a wavelength of about 550 nm. The CdS thin film is an n-type semiconductor, and may be doped with indium (In), gallium (Ga) and aluminum (Al) or the like to obtain a low resistance value.

In operation S50, a front transparent electrode 160 is formed on the buffer layer 150. The front transparent electrode 160 may be formed of a material that has a high optical transmittance and good electrical conductivity.

For example, the front transparent electrode 160 may be formed of a zinc oxide (ZnO) thin film. The ZnO thin film has a bandgap energy of about 3.3 eV, and may have a high optical transmittance of about 80% or more. At this time, the ZnO thin film may be formed by a radio frequency (RF) sputtering method using a ZnO target, a reactive sputtering method using a Zn target or an organic metal chemical vapor deposition method, etc. The ZnO thin film may be formed by doping with aluminum (Al) or boron (B) and the like to obtain a low resistance value.

Alternatively, the front transparent electrode 160 may be formed by stacking an ITO thin film having excellent electro-optical characteristics on the ZnO thin film. Also, the front transparent electrode 160 may be formed by stacking an n-type ZnO thin film having a low resistance on an undoped i-type ZnO thin film. The front transparent electrode 160 may be formed by a typical sputtering method. The front transparent electrode 160 is an n-type semiconductor such that a pn-junction is formed with the optical absorption layer 140 which is a p-type semiconductor.

In operation S60, an anti-reflective layer 170 may be additionally formed at a portion of region on the front transparent electrode 160. The anti-reflective layer 170 may reduce a reflective loss of solar light incident on the CIGS-based thin film solar cell 100. The efficiency of the CIGS-based thin film solar cell 100 may be improved by the anti-reflective layer 170. For example, the anti-reflective layer 170 may be formed of magnesium fluoride (MgF₂) thin film. The MgF₂ thin film may be formed by an E-beam evaporation method.

In operation S70, a grid electrode 180 may be formed at one side of the anti-reflective layer 170 and on the front transparent electrode 160. The grid electrode 180 is for collecting currents on a surface of the CIGS-based thin film solar cell 100. The grid electrode 180 may be formed of metals such as aluminum (Al) or nickel (Ni)/aluminum (Al), etc. The grid electrode 180 may be formed by a sputtering method. Because solar light does not incident on a portion occupied by the grid electrode 180, it is necessary to minimize the portion.

According to an embodiment of the inventive concept, since a hole injection layer is inserted between a back electrode and an optical absorption layer, an injection of holes into the back electrode becomes easy such that the efficiency of a solar cell can be improved.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A compound semiconductor solar cell, comprising:
a back electrode provided on a substrate;
a hole injection layer provided on the back electrode;
a copper indium gallium selenide (CIGS) based optical absorption layer provided on the hole injection layer; and
a front transparent electrode provided on the optical absorption layer.

2. The compound semiconductor solar cell of claim 1, wherein a difference between a valence band of the hole injection layer and a valence band of the p-type semiconductor optical absorption layer is larger than a difference between a conduction band of the hole injection layer and the valence band of the p-type semiconductor optical absorption layer.

3. The compound semiconductor solar cell of claim 2, wherein the hole injection layer comprises molybdenum (Mo) oxide.

4. The compound semiconductor solar cell of claim 3, wherein the molybdenum oxide is molybdenum trioxide.

5. The compound semiconductor solar cell of claim 1, wherein the hole injection layer is formed with a thickness of about 0.001 μm to about 1.0 μm.

6. The compound semiconductor solar cell of claim 1, wherein the optical absorption layer comprises I-III-VI₂ group compound semiconductors.

7. The compound semiconductor solar cell of claim 1, further comprises a buffer layer provided between the optical absorption layer and the front transparent electrode.

8. The compound semiconductor solar cell of claim 1, further comprising:
an anti-reflective layer provided at a portion of region on the front transparent electrode; and
a grid electrode which is provided at a side face of the anti-reflective layer and in contact with the front transparent electrode.
